(19) United States
(12) Patent Application Publication
(10) Pub. No.: US 2018/0007800 A1
(43) Pub. Date: Jan. 4, 2018

(54) LAMINATE PRODUCTION METHOD

(71) Applicant: ZEON CORPORATION, Tokyo (JP)

(72) Inventors: Natsuko SHINDOU, Tokyo (JP); Shigeru FUJITA, Tokyo (JP)

(21) Appl. No.: 15/514,493

(22) PCT Filed: Sep. 30, 2015
(86) PCT No.: PCT/IB2015/002087

§ 371 Date: Aug. 29, 2017

(30) Foreign Application Priority Data
Sep. 30, 2014 (JP) 2014-199891

(51) Int. Cl. H05K 3/40; H05K 3/22; H05K 3/00; C25D 5/02; B32B 37/06; C23C 14/20; C23C 14/34; B32B 38/00; B32B 38/10; H05K 3/46; C25D 3/38; B32B 38/04

(52) U.S. Cl. CPC H05K 3/4038; H05K 3/4644; H05K 3/22; H05K 3/005; C25D 5/022; C25D 3/38; B32B 37/06; C23C 14/205; C23C 14/34; B32B 38/0008; B32B 38/10; B32B 2038/042; B32B 2457/08

(57) ABSTRACT

To provide a manufacturing method of a laminate body, including: a step of forming onto a supporting body a curable resin composition layer formed from a thermosetting resin composition to obtain a curable resin composition layer with a supporting body; a step of laminating the curable resin composition onto a substrate on a curable resin composition layer forming surface side to obtain a pre-cured composite with a supporting body formed from a substrate and a curable resin composition layer with a supporting body; a step of performing a first heating of the pre-cured composite and thermally curing the curable resin composition layer to obtain a cured composite with a supporting body formed from a substrate and a cured resin layer with a supporting body; a step of performing hole punching from the supporting body side of the cured composite with a supporting body to form a via hole in the cured resin layer; step of removing resin residue in the via hole of the cured composite with a supporting body; a step of peeling the supporting body from the cured composite with a supporting body to obtain a cured composite formed from a substrate and a cured resin layer, and a step of forming a dry plated conductor layer by dry plating on an inner wall surface of the via hole of the cured composite and on the cured resin layer.

### TECHNICAL FIELD

The present invention relates to a method of manufacturing a laminate body wherein a conductor layer and a cured resin layer are provided on a substrate.

### BACKGROUND ART

Along with pursuing downsizing, multifunctionalization, increasing communication speeds, and the like of electronic equipment, further densification of the circuit board used in electronic equipment is required, and multilayering of circuit boards is being achieved to meet the requirements of densification. The multilayer circuit board is formed, for example, on an inner layer substrate made of an electrical insulating layer and a conductor layer formed on a surface of the electrical insulating layer, by laminating an electrical insulating layer and forming a conductor layer on the electrical insulating layer, and further repeating laminating the electrical insulating layers and forming the conductor layers.

As a method of manufacturing the laminate body for forming the multilayer circuit board, for example, Patent Document 1 discloses a manufacturing method of a multilayer printed wiring board that requires a step of heating and applying pressure to perform laminating under vacuum conditions, in a condition of directly covering a resin composition layer of an adhesive film onto at least a pattern processed portion of one surface or both surfaces on a supporting base film having a release layer and a circuit board that was pattern processed thereof, a step of thermally curing the resin composition in a condition attached to the supporting base film, a step of hole punching by a laser or drill, a step of peeling the supporting base film, a step of performing roughening treatment to a resin composition surface, and then a step of wet plating the roughened surface to form the conductor film.

In the Patent Literature 1, the resin composition is thermally cured in a condition attached to a supporting body such as a supporting base film, and thereby, foreign matter that attaches during thermal curing of the resin composition and defects such as disconnecting, shorting, and the like caused by the foreign matter are prevented. Furthermore, in Patent Literature 1, after the resin composition in the condition attached with the supporting body is thermally cured, and before the supporting body is peeled, a small diameter via hole can be formed by performing hole punching by a laser or drill.

### CITATION LIST

### Patent Literature

Patent Literature 1: JP-A-2001-196743

### SUMMARY OF INVENTION

### Problem to be Resolved by the Invention

However, when forming a conductor layer with the technology in the aforementioned Patent Literature 1, a conductor layer is formed by performing wet plating directly on a resin layer, and therefore, forming a fine conductor layer (fine wiring) with high adhesive strength is difficult, and thus miniaturization, multifunctionalization, increasing communication speeds, and the like of electronic equipment cannot be sufficiently satisfied.

An object of the present invention is to provide a method of manufacturing a laminate body provided with a cured resin layer with high adhesion to a conductor layer body, low surface roughness, and where a small diameter via hole with excellent conduction reliability and fine wiring is possible.

### Means for Resolving Problems

As a result of extensive studies in order to achieve the aforementioned object, the present inventors discovered that with the method of manufacturing a laminate body provided with a conductor layer and a cured resin layer on a substrate, a small diameter via hole with excellent conduction reliability can be formed, and an intricate conductor layer with high adhesion can be formed while keeping the surface roughness of the cured resin layer low, by forming a cured composite by heating to cure a curable resin composition layer in a condition attached to a supporting body, and then forming a via hole by making a hole in the cured resin layer, removing resin residue in the formed vial hole, peeling off the supporting body, and then forming a conductor layer by dry plating on the obtained cured composite, and thereby, the present invention is achieved.

In other words, the present invention provides:

[1] A manufacturing method of a laminate body, including: a first step of forming onto a supporting body a curable resin composition layer formed from a thermosetting resin composition to obtain a curable resin composition layer with a supporting body; a second step of laminating the aforementioned curable resin composition with a supporting body onto a substrate on a curable resin composition layer forming surface side to obtain a pre-cured composite with a supporting body formed from a substrate and a curable resin composition layer with a supporting body; a third step of performing a first heating of the aforementioned composite and thermally curing the aforementioned curable resin composition layer to form a cured resin layer to obtain a cured composite with a supporting body formed from a substrate and a cured resin layer with a supporting body; a fourth step of performing hole punching from the aforementioned supporting body side of the aforementioned cured composite with a supporting body to form a via hole in the aforementioned cured resin layer, a fifth step of removing resin residue in the via hole of the cured composite; a sixth step of peeling the aforementioned supporting body from the aforementioned cured composite with a supporting body to obtain a cured composite formed from a substrate and a cured resin layer; and a seventh step of forming a dry plated conductor layer by dry plating on an inner wall surface of the via hole of the aforementioned cured composite and on the aforementioned cured resin layer;

[2] The manufacturing method of a laminate body according to [1], where the removal of resin residue in a via hole in the fifth step is performed by plasma treatment;

[3] The manufacturing method of a laminate body according to [1] or [2], where the dry plating in the seventh step is performed by a sputtering method;

[4] The manufacturing method of a laminate body according to any one of [1] to [3], further including an eighth step of further performing wet plating on the drying plated conductor layer to form a wet plated conductor layer on the dry plated conductor layer;

[5] The manufacturing method of a laminate body according to [4], where the via hole is filled with the wet plate conductor layer formed on the dry plated conductor layer in the eighth step;

[6] A laminate body obtained by the manufacturing method according to any one of [1] to [5]; and

[7] A multilayer circuit board comprising the laminate body according to [6].

### Effect of the Invention

The manufacturing method of the present invention can provide a laminate body with a cured resin layer with high adhesion to the laminate body, that has low surface roughness, and where a small diameter via hole with excellent conduction reliability and fine wiring are possible, and can provide a multilayer circuit board by using the laminate body.

### DESCRIPTION OF EMBODIMENTS

The manufacturing method of a laminate body of the present invention is a method of manufacturing the laminate body wherein a conductor layer and a cured resin layer are provided on a substrate, including:

(1) a first step of forming onto a supporting body a curable resin composition layer formed from a thermosetting resin composition to obtain a curable resin composition layer with a supporting body;

(2) a second step of laminating the aforementioned curable resin composition layer with a supporting body onto a substrate on a curable resin composition layer forming surface side to obtain a pre-cured composite with a supporting body formed from a substrate and a curable resin composition layer with a supporting body;

(3) a third step of performing heating of the aforementioned composite and thermally curing the aforementioned curable resin composition layer to form a cured resin layer to obtain a cured composite with a supporting body formed from a substrate and a cured resin layer with a supporting body;

(4) a fourth step of performing hole punching from the aforementioned supporting body side of the aforementioned cured composite with a supporting body to form a via hole in the aforementioned cured resin layer;

(5) a fifth step of removing resin residue in the via hole of the aforementioned cured composite;

(6) a sixth step of peeling the aforementioned supporting body from the aforementioned cured composite with a supporting body to obtain a cured composite formed from a substrate and a cured resin layer; and

(7) an eighth step of forming a conductor layer on an inner wall surface of the via hole of the aforementioned cured composite and on the aforementioned cured resin layer.

### First Step

The first step of the manufacturing method of the present invention is a step of forming onto a supporting body a curable resin composition layer formed from a thermosetting resin composition to obtain a curable resin composition layer with a supporting body.

The supporting body used in the first step of the manufacturing method of the present invention is not particularly limited, but includes film members, plate members, or the like, and specific examples include polyethylene terephthalate films, polypropylene films, polyethylene films, polycarbonate films, polyethylene naphthalate films, polyarylate films, nylon films, polytetrafluoroethylene films, and other polymer films, plate or film glass substrates, and the like. In order to make peeling from the cured resin layer easier, in the fifth step described later, the supporting body preferably has a release layer formed on a surface thereof by a release treatment, and preferably a polyethylene terephthalate film with a release layer.

The thickness of the supporting body used in the first step of the manufacturing method of the present invention is not particularly limited, but is preferably 5 to 200 μm, more preferably 10 to 150 μm, and even more preferably 20 to 60 μm. By using a supporting body with a thickness within the aforementioned range, the workability of the curable resin composition layer with a supporting body can be favorable.

Furthermore, the thermosetting resin composition for forming the curable resin composition layer usually contains a curable resin and a curing agent. The curable resin is not particularly limited so long as the curable resin exhibits thermal curability when combined with the curing agent, and has electrical insulating properties, and examples include epoxy resins, maleimide resins, (meth)acrylic resins, diallyl phthalate resins, triazine resins, alicyclic olefin polymers, aromatic polyether polymers, benzocyclobutene polymers, cyanate ester polymer polyimides, and the like. The resins may be used independently or in a combination of two or more types.

A case of using an epoxy resin as the curable resin is described below as an example.

The epoxy resin is not particularly limited, and for example, a polyvalent epoxy compound (14) with a biphenyl structure and/or a condensed polycyclic structure and the like can be used. The polyvalent epoxy compound (A) with a biphenyl structure and/or condensed polycyclic structure (hereinafter may be abbreviated as polyvalent epoxy compound (A)) is a compound having at least one biphenyl structure or condensed polycyclic structure, and having at least two epoxy groups (oxirane ring) in one molecule.

The biphenyl structure refers to a structure wherein two benzene rings are connected by a single bond. The biphenyl structure in the obtained cured resin usually configures a main chain in the resin, but can be present in a side chain.

Furthermore, the condensed polycyclic structure refers to a structure formed by condensation of two or more monocyclic groups. The ring that configures the condensed polycyclic structure may be alicyclic or aromatic, and may contain a hetero atom. The number of condensed rings is not particularly limited, but is preferably 2 rings or more, and practically, the upper limit is approximately 10 rings from the perspective of increasing heat resistance and mechanical strength of the obtained cured resin layer. Examples of the condensed polycyclic structure include dicyclopentadiene structures, naphthalene structures, fluorene structures, anthracene structures, phenanthrene structures, triphenylene structures, pyrene structures, ovalene structures, and the like. Similar to the biphenyl structure, the condensed polycyclic structure in the obtained cured resin usually configures a main chain in the resin contained in the cured resin layer, but can be present in a side chain.

The polyvalent epoxy compound (A) used in the present invention has a biphenyl structure, condensed polycyclic structure, or both biphenyl structure and condensed polycyclic structure, but from the perspective of increasing heat resistance and mechanical strength of the obtained cured resin layer, the polyvalent epoxy compound (A) preferably has a biphenyl structure, and more preferably has a biphenyl aralkyl structure.

Furthermore, if a polyvalent epoxy compound (A) with a biphenyl structure (includes polyvalent epoxy compounds having both a biphenyl structure and a condensed polycyclic structure) and a polyvalent epoxy compound (A) with a condensed polycyclic structure are used in combination, from the perspective of improving heat resistance and electrical properties of the cured resin layer, usually the compounding ratio thereof is preferably a weight ratio (polyvalent epoxy compound having a biphenyl structure/polyvalent epoxy compound having a condensed polycyclic structure) of 3/7 to 7/3.

The polyvalent epoxy compound (A) used in the present invention has at least two epoxy groups in one molecule, and the structure thereof is not limited as long as the compound has a biphenyl structure and/or a condensed polycyclic structure, but from the perspective of the cured resin layer having excellent heat resistance and mechanical strength, the compound is preferably a novolak epoxy compound having a biphenyl structure and/or a condensed polycyclic structure. Examples of the novolak epoxy compound include phenol novolak epoxy compounds, cresol novolak epoxy compounds, and the like.

In order to achieve good curing reactivity, the polyvalent epoxy compound (A) usually has an epoxy equivalent of 100 to 1500 equivalents, and preferably 150 to 500 equivalents. Note that “epoxy equivalent” in the present specification is the number of grams (g/eq) of the epoxy compound containing 1 gram equivalent of an epoxy group, which can be measured according to a method of JIS K 7236.

The polyvalent epoxy compound (A) used in the present invention can be appropriately manufactured according to a known method, and can also be obtained as a commercially available product.

Examples of commercially available product of the polyvalent epoxy compound (A) having a biphenyl structure include novolak epoxy compounds having a biphenyl aralkyl structure such as trade name “NC3000-FH, NC3000-H, NC3000, NC3000-L, NC3100” (manufactured by Nippon Kayaku Co., Ltd.); epoxy compounds having a tetramethylbiphenyl structure such as trade name “YX-4000” (manufactured by Mitsubishi Chemical Corporation); and the like. Furthermore, examples of the commercially available product of the polyvalent epoxy compound having a condensed polycyclic structure include novolak epoxy compounds having a dicyclopentadiene structure, such as trade name “Epiclon HP7200L, Epiclon HP7200, Epiclon HP7200H, Epiclon HP7200HH, Epiclon HP7200HHH” (“Epiclon” is a registered trademark, manufactured by DIC Corporation), trade name “Tactix 556, Tactix 756” (“Tactix” is a registered trademark, manufactured by Huntsman Advanced Materials), trade name “XD-1000-1L, XD-1000-2L” (manufactured by Nippon Kayaku Co., Ltd.), and the like. The polyvalent epoxy compounds (A) can be used independently or in a combination of two or more types.

Furthermore, when using the polyvalent epoxy compound (A) having a biphenyl structure and/or a condensed polycyclic structure, an epoxy compound (B) containing a trivalent or higher polyvalent glycidyl group other than the aforementioned phenol novolak epoxy compound may be used in a combination, and by further using the epoxy compound (B) containing a trivalent or higher polyvalent glycidyl group, heat resistance or electrical properties of the obtained cured resin layer can be further improved.

The epoxy compound (B) containing a trivalent or higher polyvalent glycidyl group other than the phenol novolak epoxy compound is preferably a compound with an epoxy equivalent of 250 or less, and more preferably a compound with 220 or less, from the perspective of heat resistance and electrical properties of the obtained cured resin layer. Specific examples include: polyvalent phenol epoxy compounds having a structure where a hydroxyl group of the trivalent or higher polyvalent phenol is glycidylated, glycidyl amine epoxy compounds where an amino group of a compound containing a divalent or higher polyvalent aminophenyl group is glycidylated, compounds containing a polyvalent glycidyl group where a trivalent or higher compound having the phenol structure or aminophenyl structure in the same molecule is glycidylated, and the like.

The polyvalent phenol epoxy compound having a structure where a hydroxyl group of the trivalent or higher polyvalent phenol is glycidylated is not particularly limited, but is preferably a trivalent or higher polyvalent hydroxyphenylalkane epoxy compound. Here, the trivalent or higher polyvalent hydroxyphenylalkane epoxy compound is a compound having a structure where a hydroxyl group of an aliphatic hydrocarbon substituted with three or more hydroxyphenyl groups.

The epoxy compound (B) containing a trivalent or higher polyvalent glycidyl group used in the present invention can be appropriately manufactured according to a known method, and can also be obtained as a commercially available product. Examples of the commercially available product of the trishydroxyphenylmethane epoxy compound include trade name “EPPN-503, EPPN-502H, EPPN-501H” (manufactured by Nippon Kayaku Co Ltd.), trade name “TACTIX-742” (manufactured by The Dow Chemical Company), “JER1032H60” (manufactured by Mitsubishi Chemical Corporation), and the like. Furthermore, examples of the commercially available product of the tetrakis hydroxyphenylethane epoxy compound include trade name “JER1031S” (manufactured by Mitsubishi Chemical Corporation) and the like. Examples of the glycidyl amine epoxy compound include trade name “YH-434, YH-434L” (manufactured by Nippon Steel & Sumikin Chemical Co., Ltd.) as a tetravalent glycidyl amine epoxy compound, trade name “jER604” (manufactured by Mitsubishi Chemical Corporation), and the like. Examples of the compound containing a polyvalent glycidyl group where a trivalent or higher compound having a phenol structure or aminophenyl structure in the same molecule is glycidylated include trade name “jER630” (manufactured by Mitsubishi Chemical Corporation) as a trivalent glycidyl amine epoxy compound, or the like.

In the case where the epoxy compound (B) containing a trivalent or higher polyvalent glycidyl group is used in a combination, the content ratio of the epoxy compound (B) containing a trivalent or higher polyvalent glycidyl group is not particularly limited, but is preferably 0.1 to 40 wt. %, more preferably 1 to 30 wt. %, and particularly preferably 3 to 25 wt. % with regard to a total of 100 wt. % of the epoxy compound that is used. By setting the amount of the epoxy compound (B) containing a trivalent or higher polyvalent glycidyl group in the thermosetting resin composition to the aforementioned range in relation to the aforementioned polyvalent epoxy compound (A), the obtained cured resin layer can have further increased heat resistance, electrical properties, and adhesion to the conductor layer.

Furthermore, in addition to the polyvalent epoxy compound (A) and epoxy compound (B) containing a trivalent or higher polyvalent glycidyl group, the thermosetting resin composition used in the present invention can appropriately contain additional epoxy compounds other than the aforementioned epoxy compounds. Examples of additional epoxy compounds include epoxy compounds containing phosphorus. An example of epoxy compounds containing phosphorus preferably includes epoxy compounds having a phosphaphenanthrene structure, and by further using the epoxy compound having a phosphaphenanthrene structure, the obtained cured resin layer can have further improved heat resistance, electrical properties, and adhesion to the conductor layer.

The epoxy compound having a phosphaphenanthrene structure may be an epoxy compound having a phosphaphenanthrene structure as expressed by the following Formula (1), and is not particularly limited, and examples include biphenyl epoxy compounds having a phosphaphenanthrene structure, bisphenol epoxy compounds having a phosphaphenanthrene structure, phenolic novolak epoxy compounds having a phosphaphenanthrene structure, and the like.

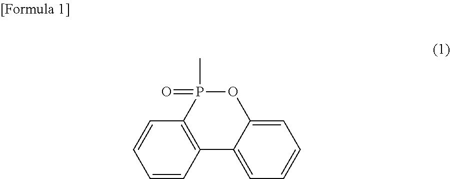 [SMILES: CP1(=O)Oc2ccccc2-c2ccccc21]

Furthermore, the thermosetting resin composition used in the present invention may contain a phenol resin (C) containing a triazine structure. The phenol resin (C) containing a triazine structure is a condensation polymer of aromatic hydroxy compounds such as phenol, cresol, and naphthol, compounds having a triazine ring such as melamine, and benzenguanamine, and formaldehyde. The phenol resin (C) containing a triazine structure typically has a structure as expressed by the following General Formula (2).

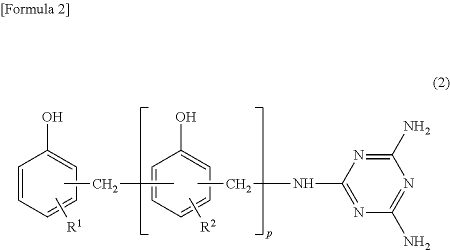

(In Formula (2), R1, R2 are a hydrogen atom or a methyl group, and p is an integer of 1 to 30. Furthermore, R1, R2 may be the same or different from each other, and furthermore, when p is 2 or higher, a plurality of R2 may be the same or different from each other. Furthermore, in Formula (2), in at least one of the amino groups, a hydrogen atom contained in the amino group can be substituted with another group (an alkyl group or the like, for example).)

The phenol resin (C) containing a triazine structure acts as a curing agent of the epoxy compound by the presence of a phenolic active hydroxy group, and particularly, the obtained cured resin layer exhibits excellent adhesion to the substrate by containing the phenol resin (C) containing a triazine structure.

The phenol resin (C) containing a triazine structure can be manufactured according to a known method, and can also be obtained as a commercially available product. Examples of the commercially available product include trade name “LA7052, LA7054, LA3018, LA1356” (manufactured by DIC Corporation) or the like. The phenol resin (C) containing a triazine structure can be used independently or in a combination of two or more types.

The added amount of the phenol resin (C) containing a triazine structure in the thermosetting resin composition used in the present invention is in a range of preferably 1 to 60 parts by weight, more preferably 2 to 50 parts by weight, even more preferably 3 to 40 parts by weight, and particularly preferably 4 to 20 parts by weight with regard to a total of 100 parts by weight of the epoxy compound that is used.

Furthermore, the equivalent ratio of the epoxy compound that is used and the phenol resin (C) containing a triazine structure in the thermosetting resin composition used in the present invention (ratio of the total number of active hydroxyl group content in the phenol resin (C) containing a triazine structure, with regard to the total number of epoxy groups of the epoxy compound that is used (active hydroxyl group content/epoxy group content)) is preferably within a range of 0.01 to 0.6, more preferably 0.05 to 0.4, and even more preferably 0.1 to 0.3. By setting the added amount of the phenol resin (C) containing a triazine structure to the aforementioned range, electrical properties and heat resistance of the obtained cured resin layer can be improved. Note that the equivalent ratio of the epoxy compound that is used and the phenol resin (C) containing a triazine structure can be determined from the total epoxy equivalent of the epoxy compound that is used, and the total active hydroxyl group equivalent of the phenol resin (C) containing a triazine structure.

Furthermore, the thermosetting resin composition used in the present invention preferably contains an active ester compound (D) in addition to the aforementioned components. The active ester compound (D) preferably has an active ester group, but in the present invention, the active ester compound (D) is preferably a compound having at least two active ester groups in a molecule. The active ester compound (D) acts as a curing agent of the epoxy compound used in the present invention, similarly to the phenol resin (C) containing a triazine structure, by an epoxy site and an epoxy group reacting by heating.

From the perspective of increasing the heat resistance of the obtained cured resin layer, the active ester compound (D), is preferably an active ester compound obtained by reacting a carboxylic acid compound and/or thiocarboxylic acid compound with a hydroxy compound and/or thiol compound, more preferably an active ester compound obtained by reacting one or two types or more selected from a group of carboxylic acid compounds, phenol compounds, naphthol compounds, and thiol compounds, and particularly preferably an aromatic compound obtained by reacting a carboxylic acid compound with an aromatic compound having a phenolic hydroxyl group, and having at least two active ester groups in a molecule. The active ester compound (D) may have a straight chain or multi-branched shape, and in the case where the active ester compound (D) is derived from a compound having at least two carboxylic acids in a molecule, as an example, if the compound having at least two carboxylic acids in a molecule contains an aliphatic chain, compatibility with an epoxy compound can be increased, and if the compound contains an aromatic ring, the heat resistance will be increased.

Specific examples of the carboxylic acid compound for forming the active ester compound (D) include benzoic acids, acetic acids, succinic acids, maleic acids, itaconic acids, phthalic acids, isophthalic acids, terephthalic acids, pyromellitic acids, and the like. Of these, from the perspective of increasing the heat resistance of the obtained cured resin layer, the carboxylic acid compound is preferably a succinic acid, maleic acid, itaconic acid, phthalic acid, isophthalic acid, or terephthalic acid, more preferably a phthalic acid, isophthalic acid, and diphthalic acid, and even more preferably an isophthalic acid, and terephthalic acid.

Specific examples of the thiocarboxylic acid compound for forming the active ester compound (D) include thioacetic acids, thiobenzoic acids, and the like.

Specific examples of the hydroxy compound for forming the active ester compound (D) include hydroquinone, resorcin, bisphenol A, bisphenol F, bisphenol S, phenophtharin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxy enzophenone, trihydroxybenzophenone, tetrahydroxybenrophenone, phlorogluch, benzene triol, dicyclopentadienyl diphenol, phenol novdlak, and the like. Of these, from the perspective of improving solubility of the active ester compound (D) as well as increasing the heat resistance of the obtained cured resin layer, the hydroxy compound is preferably 1,5-dihydroxynaphthalene, 1,6-dihydroxynaphthalene, 2,6-dihydroxynaphthalene, dihydroxybenzophenone, trihydroxybenzophenone, tetrahydroxybenzophenone, dicyclopentadienyl diphenol, and phenol novolac, more preferably dihydroxybenzophenone, trihydroxybenzophenone, tetrahydro, roxybensophenone, dicyclopentadienyl diphenol, and phenol novolak, and even more preferably dicyclopentadienyl diphenol, and phenol novolak.

Specific examples of the thiol compound for forming the active ester compound (D) include benzenedithiol, triazindithiol, and the like.

The manufacturing method of the active ester compound (D) is not particularly limited, and the compound can be manufactured by a known method. For example, the compound can be obtained by condensation reaction of the aforementioned carboxylic acid compound and/or thiocarboxylic acid compound with a hydroxy compound and/or thiol compound.

For example, an aromatic compound having an active ester group disclosed in JP-A-2002-12650, a polyfunctional polyester disclosed in JP-A-2004-277460, and commercially available products can be used as the active ester compound (D). Examples of the commercially available products include trade name “EXB 9451, EXB 9460, EXB 9460S, Epiclon HPC-8000-65T” (“Epiclon” is a registered trademark, manufactured by DIC Corporation), trade name “DC 808” (manufactured by Japan Epoxy Resins Co., Ltd.), trade name “YLH1026” (manufactured by Japan Epoxy Resins Co., Ltd.) and the like.

The added amount of the active ester compound (D) in the thermosetting resin composition used in the present invention is in a range of preferably 10 to 150 parts by weight, more preferably 15 to 130 parts by weight, and even more preferably 20 to 120 parts by weight with regard to a total of 100 parts by weight of the epoxy compound that is used.

Furthermore, the equivalent ratio of the epoxy compound that is used and the active ester compound (D) in the thermosetting resin composition used in the present invention (ratio of the total number of reactive groups of the active ester compounds (D), with regard to the total number of epoxy groups of the epoxy compound that is used (active ester group content/epoxy group content)) is preferably within a range of 0.5 to 1.1, more preferably 0.6 to 0.9, and even more preferably 0.65 to 0.85.

Furthermore, the equivalent ratio of the epoxy compound that is used, the phenol resin (C) containing a triazine structure, and the active ester compound (D) in the thermosetting resin composition used in the present invention (ratio of the total number of epoxy groups in the epoxy compound that is used, with regard to the active hydroxyl group of the phenol resin (C) containing a triazine structure and the active ester group of the active ester compound (D) (epoxy group content/(active hydroxyl group content+active ester group content)) is within a range of usually less than 1.1, preferably 0.6 to 0.99, and more preferably 0.65 to 0.95. By setting the equivalent ratio to the aforementioned range, the obtained cured resin layer can exhibit good electric properties. Note that the equivalent ratio of the epoxy compound that is used, aid the phenol resin (C) containing a triazine structure and the active ester compound (D) can be determined from the total epoxy equivalent of the epoxy compound that is used, and the total active hydroxyl group equivalent of the phenol resin (C) containing a triazine structure and the total active ester equivalent of the active ester compound (D).

In addition to the aforementioned components, the thermosetting resin composition used in the present invention can further contain other components as described below.

The obtained cured resin layer can have low expansion properties by adding a filler to the thermosetting resin composition. A known inorganic filler or organic filler can be used as the filler, but an inorganic filler is preferable. Specific examples of the inorganic filler include calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, clay, and the like. Note that the filler that is used can be previously surface treated with a silane coupling agent or the like. The amount of filler in the thermosetting resin composition used in the present invention is not particularly limited, but is usually 30 to 90 wt. % in terms of solid content.

Furthermore, an alicyclic olefin polymer having a polar group can be added to the thermosetting resin composition. Examples of the polar group include groups having a structure that can react with an epoxy group and form a covalent bond, and groups containing a hetero atom and having no reactivity with epoxy groups, but preferably, the groups contain a hetero atom and have no reactivity with epoxy groups. The alicyclic olefin polymer has no reactivity with epoxy groups, and therefore, does not substantially contain a functional group having reactivity with epoxy groups. Herein, “does not substantially contain a functional group having reactivity with epoxy groups” means that the alicyclic olefin polymer does not contain a functional group having reactivity with epoxy groups to a degree of inhibiting the expression of the effect of the present invention. An example of the functional group having reactivity with epoxy groups include groups having a structure that can react with an epoxy group and form a covalent bond, and examples thereof include primary amino groups, secondary amino groups, mercapto groups, carboxyl groups, carboxylic acid anhydride groups, hydroxy groups, epoxy groups, and other functional groups containing a hetero atom that reacts with an epoxy group and forms a covalent bond.

The aforementioned alicyclic olefin polymer can be easily obtained by appropriately combining, for example, an alicyclic olefin monomer (a) containing no hetero atoms and containing an aromatic ring, alicyclic olefin monomer (b) containing no aromatic rings and containing a hetero atom, alicyclic olefin monomer (c) containing both an aromatic ring and a hetero atom, and a monomer (d) containing neither aromatic rings nor hetero atoms, and that can polymerize with the alicyclic olefin monomers (a) to (c), and polymerizing according to a known method. The obtained polymer may be further hydrogenated.

The added amount of the alicyclic olefin polymer having a polar group in the thermosetting resin composition used in the present invention is not particularly limited, but is usually 50 parts by weight or less, and preferably 35 parts by weight or less, with regard to a total of 100 parts by weight of the epoxy compound that is used.

The thermosetting resin composition may optionally contain a curing promoting agent. The curing promoting agent is not particularly limited, but examples thereof include aliphatic polyamines, aromatic polyamines, secondary amines, tertiary amines, acid anhydrides, imidazole derivatives, organic acid hydrazides, dicyandiamides, derivatives thereof, urea derivatives, and the like. Of these, imidazole derivatives are particularly preferable.

The imidazole derivative is not particularly limited as long as it is a compound having an imidazole skeleton, and examples include 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, 2-heptadecylimidazole, and other alkyl-substituted imidazole compounds; 2-phenylimidazole, 2-phenyl-4-methylimidazole, 1-benzyl-2-methylimidazole, 1-benzyl-2-ethylimidazole, 1-benzyl-2-phenylimidazole, benzimidazole, 2-ethyl-(2′-cyanoethyl) imidazole, and other imidazole compounds substituted with a hydrocarbon group containing a cyclic structure such as an aryl group and an aralkyl group. These may be used independently as one type or may be used in a combination of two or more types.

The added amount of the curing promoting agent in the thermosetting resin composition used in the present invention is usually 0.1 to 10 parts by weight and preferably 0.5 to 8 parts by weight with regard to a total of 100 parts by weight of the epoxy compound that is used.

Furthermore, for the purpose of improving flame retardancy of the obtained cured resin layer, a flame retardant that is added to a general resin composition for forming an electrical insulating film such as halogen type flame retardants or phosphate ester type flame retardants may be appropriately added to the thermosetting resin composition.

Furthermore, if desired, flame retardant auxiliary agents, heat resistant stabilizers, weather resistant stabilizers, antioxidants, ultraviolet absorbers (laser processability improver), leveling agents, antistatic agents, slip agents, anti-blocking agents, anti-fogging agents, lubricants, dyes, natural oils, synthetic oils, waxes, emulsions, magnetic materials, dielectric property adjusting agents, toughening agents, and other known components may be appropriately added to the thermosetting resin composition of the present invention.

The method of preparing the thermosetting resin composition used in the present invention is not particularly limited, and the aforementioned components may be mixed as they are, may be mixed as a state dissolved or dispersed in an organic solvent, or a composition in a state wherein a portion of the components are dissolved or dispersed in an organic solvent may be prepared, and then the remaining components may be mixed into the composition.

In the first step of the manufacturing method of the present invention, the thermosetting resin composition described above can be used to form onto the supporting body the curable resin composition layer made of the thermosetting resin composition to obtain the curable resin composition layer with a supporting body.

The method for forming onto the supporting body the curable resin composition layer made from the thermosetting resin composition is not particularly limited, but a method of adding an organic solvent to the thermosetting resin composition as desired, and then coating, spraying, or casting the composition onto the supporting body, and then drying, is preferable.

The thickness of the curable resin composition layer is not particularly limited, but from the perspective of workability or the like, the thickness is usually 5 to 50 μm, preferably 7 to 40 μm, more preferably 10 to 35 μm, and even more preferably 10 to 30 μm.

Examples of the method of coating the thermosetting resin composition include dip coating, roller coating, curtain coating, die coating, slit coating, gravure coating, and the like.

Note that in addition to a case where the thermosetting resin composition is uncured, the curable resin composition layer may be in a semi-cured state. Herein, “uncured” refers to a state where the entire curable resin substantially dissolves when the curable resin composition is immersed into a solvent that can dissolve the curable resin (epoxy resin, for example) that is used for preparing the thermosetting resin composition. Furthermore, semi-cured refers to a state where the composition is partially cured where further curing can be performed if further heating is performed, and preferably a state where a portion (specifically an amount of 7 wt. % or greater with a portion remaining) of the curable resin dissolves in a solvent that can dissolve the curable resin used for preparing the thermosetting resin composition, or a state where the volume after immersing the compact into the solvent for 24 hours is 200% or greater than the volume before immersing (swelling ratio).

Furthermore, after the thermosetting resin composition is coated onto the supporting body, drying may be performed if desired. The drying temperature is preferably a temperature at which the thermosetting resin composition is not cured, and may be set according to the type of curable resin that is used, but is usually 20 to 300° C., and preferably 30 to 200° C. If the drying temperature is too high, the curing reaction advances excessively and there is a risk where the obtained curable resin composition layer may not be in an uncured or semi-cured state. Furthermore, the drying time is usually 30 seconds to 1 hour, and preferably 1 minute to 30 minutes.

Furthermore, in the first step of the manufacturing method of the present invention, the curable resin composition layer can have a structure of two layers or more. For example, before forming the resin layer (hereinafter, the resin layer is referred to as “the first resin layer”) formed by using the aforementioned thermosetting resin composition (hereinafter, the thermosetting resin composition is referred to as “the first thermosetting resin composition”), a second thermosetting resin composition which is different from the first thermosetting resin composition is used to form on the supporting body a second resin layer which is different from the first resin layer, and by forming on this the first resin layer by using the first thermosetting resin composition layer, the curable resin composition layer can have a two layer structure. Note that in this case, the second resin layer can be used as a layer to be plated for forming the conductor layer by electroless plating or the like, and the first resin layer can be used as an adhesive layer for adhering with the substrate, for example.

The second thermosetting resin composition for forming the second resin layer is not particularly limited, and usually, a composition containing a curable resin which is different from the first thermosetting resin composition and a curing gent can be used, but from the perspective of improving electrical properties and heat resistance of the curable resin composition layer, the curable resin preferably contains an alicyclic olefin polymer having a polar group.

The alicyclic olefin polymer having a polar group is not particularly limited, and examples of the alicyclic structure include cycloalkane structures, cycloalkene structures, and the like. From the perspective of having excellent mechanical strength and heat resistance, having a cycloalkane structure is preferable. Furthermore, examples of the polar group contained in the alicyclic olefin polymer include alcoholic hydroxyl groups, phenolic hydroxyl groups, carboxyl groups, alkoxyl groups, epoxy groups, glycidyl groups, oxycarbonyl groups, carbonyl groups, amino groups, carboxylic acid anhydride groups, sulfonic acid groups, phosphoric acid groups, and the like. Of these, carboxyl groups, carboxylic acid anhydride groups, and phenolic hydroxyl groups are preferable, and carboxylic acid anhydride groups are more preferable.

Furthermore, the curing agent contained in the second thermosetting resin composition is not particularly limited as long as the curing agent can form a crosslinked structure to the alicyclic olefin polymer having a polar group by heating, and a curing agent that is added to the general resin composition for forming an electrical insulating film can be used. The curing agent is preferably a compound having two or more functional groups that can form a bond by reacting with the polar group of the alicyclic olefin polymer having a polar group that is used.

For example, examples of the curing agent that is preferably used in cases using an alicyclic olefin polymer having a carboxyl group, carboxylic acid anhydride group, or phenolic hydroxyl group as the alicyclic olefin polymer having a polar group, include polyvalent epoxy compounds, polyvalent isocyanate compounds, polyvalent amine compounds, polyvalent hydrazide compounds, aziridine compounds, basic metal oxides, organometallic halides, and the like. One type thereof may be used independently, or two or more types thereof may be used in combination. Furthermore, the compounds can be used in combination with peroxides to use as a curing agent. Of these, from the perspective of having gentle reactivity between the alicyclic olefin polymer having a polar group and the polar group thereof, the curing agent is preferably a polyvalent epoxy compound, and particularly preferably a glycidyl ether type epoxy compound or alicyclic polyvalent epoxy compound.

The added amount of the curing agent in the second thermosetting resin composition is preferably within a range of 1 to 100 parts by weight, more preferably 5 to 80 parts by weight, and even more preferably 10 to 50 parts by weight with regard to 100 parts by weight of the alicyclic olefin polymer having a polar group. By setting the added amount of the curing agent to the aforementioned range, mechanical strength and electrical properties of the cured resin layer can be favorable.

Furthermore, the second thermosetting resin composition may contain hindered phenol compounds or hindered amine compounds in addition to the aforementioned components.

The added amount of the hindered phenol compound in the second thermosetting resin composition is not particularly limited, but preferably within a range of 0.04 to 10 parts by weight, more preferably 0.3 to 5 parts by weight, and even more preferably 0.5 to 3 parts by weight with regard to 100 parts by weight of the alicyclic olefin polymer having a polar group. By setting the added amount of the hindered phenol compound to the aforementioned range, mechanical strength and electrical properties of the cured resin layer can be favorable.

Furthermore, the hindered amine compound is a compound having in a molecule at least one 2,2,6,6-tetraalkylpiperidine group having a secondary amine or tertiary amine at position 4. The number of carbon atoms of alkyl is usually 1 to 50. The hindered amine compound is preferably a compound having in a molecule at least one 2,2,6,6-tetramethylpiperidyl group having a secondary amine or tertiary amine at position 4. Note that in the present invention, a hindered phenol compound and hindered amine compound are preferably used in combination.

The added amount of the hindered amine compound is not particularly limited, but is usually 0.02 to 10 parts by weight, preferably 0.2 to 5 parts by weight, and more preferably 0.25 to 3 parts by weight with regard to 100 parts by weight of the alicyclic olefin polymer having a polar group. By setting the added amount of the hindered amine compound to the aforementioned range, mechanical strength and electrical properties of the cured resin layer can be made favorable.

Furthermore, the second thermosetting resin composition may contain a curing promoting agent in addition to the aforementioned components. A curing promoting agent added to the general resin composition for forming an electrical insulating film is preferably used as the curing promoting agent, and a curing promoting agent similar to the first thermosetting resin composition can be used, for example. The added amount of the curing promoting agent in the second thermosetting resin composition may be appropriately selected according to the purpose of use, but is preferably 0.001 to 30 parts by weight, more preferably 0.01 to 10 parts by weight, and even more preferably 0.03 to 5 parts by weight with regard to 100 parts by weight of the alicyclic olefin polymer having a polar group.

Furthermore, the second thermosetting resin composition may contain a filler in addition to the aforementioned components. A similar filler as the filler used in the first thermosetting resin composition can be used as the filler. The added amount of the filler in the second thermosetting resin composition is usually 1 to 50 wt. %, preferably 2 to 45 wt. %, and more preferably 3 to 35 wt. % in terms of solid content.

Furthermore, in addition to the aforementioned components, curing promoting agents, flame retardants, flame retardant auxiliary agents, heat resistant stabilizers, weather resistant stabilizers, antioxidants, ultraviolet absorbers (laser processability improver), leveling agents, antistatic agents, slip agents, anti-blocking agents, anti-fogging agents, lubricants, dyes, natural oils, synthetic oils, waxes, emulsions, magnetic materials, dielectric property adjusting agents, toughening agents, and other known components may be appropriately added to the second thermosetting resin composition, similarly to the first thermosetting resin composition.

The manufacturing method of the second thermosetting resin composition is not particularly limited, and the aforementioned components may be mixed as they are, or may be mixed in a state dissolved or dispersed in an organic solvent, or a composition in a state wherein a portion of the components are dissolved or dispersed in an organic solvent may be prepared, and then the remaining components may be mixed into the composition.

In the first step in the manufacturing method of the present invention, in the case of making the curable resin composition layer have a two-layer structure with the first resin layer and the second resin layer, the following two methods may be used, for example. In other words, manufacturing can be performed by (1) a method of manufacturing by coating, spraying, or casting the second thermosetting resin composition onto the supporting body, drying if desired to form the second resin layer, and then further coating or casting the first thermosetting resin composition thereon, and drying if desired to form the first resin layer, or (2) a method of manufacturing by coating, spraying, or casting the second thermosetting resin composition onto the supporting body, drying if desired to obtain the second resin layer with a supporting body, and then coating, spraying, or casting the obtained second resin layer with a supporting body and the first thermosetting resin composition onto a different supporting body, drying if desired, laminating with the first resin layer with a supporting body, integrating the compacts, and then peeling the supporting body from the first resin layer side. Of these manufacturing methods, the manufacturing method (1) is preferable from the perspective of having an easier process and having excellent productivity.

In the manufacturing method (1), when coating, spraying, or casting the second thermosetting resin composition onto the supporting body, or when coating, spraying, or casting the first thermosetting resin composition onto the second resin layer formed by using the second thermosetting resin composition, or in the manufacturing method (2), when obtaining the second resin layer with a supporting body and the first resin layer with a supporting body by using the second thermosetting resin composition and the first thermosetting resin composition, adding an organic solvent as desired to the second thermosetting resin composition or the first thermosetting resin composition and then coating, spraying, or casting onto the supporting body is preferable.

The thickness of the second resin layer and the first resin layer in the manufacturing methods (1), (2) is not particularly limited, but the thickness of the second resin layer is preferably 0.5 to 10 μm, more preferably 1 to 8 μm, and even more preferably 2 to 5 μm, and furthermore, the thickness of the first resin layer is preferably 4 to 45 μm, more preferably 7 to 40 μm, and even more preferably 9 to 29 μm. If the thickness of the second resin layer is too thin, there is a risk that the formative of the conductor layer may be reduced when the second resin layer is used as a layer to be plated and the conductor layer is formed by the dry plating. On the other hand, if the thickness of the second resin layer is too thick, there is a risk that the linear expansion of the cured resin layer may increase. Furthermore, if the thickness of the first resin layer is too thin, there are cases where the wiring embedding properties may be reduced.

Examples of the method of coating the second thermosetting resin composition and the first thermosetting resin composition include dip coating, roller coating, curtain coating, die coating, slit coating, gravure coating, and the like.

Furthermore, the drying temperature is preferably a temperature at which the second thermosetting resin composition and the first thermosetting resin composition are not cured, and is usually 20 to 300° C., and preferably 30 to 200° C. Furthermore, the drying time is usually 30 seconds to 1 hour, and preferably 1 minute to 30 minutes.

### Second Step

The second step of the manufacturing method of the present invention is a step of laminating the curable resin composition with a supporting body that was obtained in the aforementioned first step onto a substrate on a curable resin composition layer forming surface side to obtain a pre-cured composite with a supporting body.

The substrate is not particularly limited, and examples include: substrates having a conductor layer on a surface thereof, or the like. The substrate having a conductor layer on the surface thereof has a conductor layer on a surface of an electrical insulating substrate, and examples of the electrical insulating substrate include products that were formed by curing a resin composition containing a known electrical insulating material (alicyclic olefin polymers, epoxy compounds, maleimide resin, (meth) acrylic resin, diallyl phthalate resin, triazine resin, polyphenylene ether, glass, and the like, for example). Furthermore, the conductor layer is not particularly limited, but is usually a layer containing a wiring formed by a conductive body such as conductive metal or the like, and may further contain various circuits. Configuration, thickness, and the like of the wiring and circuit are not particularly limited. Specific examples of the substrate having a conductor layer on a surface thereof include printed-wiring assemblies, silicon wafer substrates, and the like. The thickness of the substrate having a conductor layer on a surface thereof is usually 10 μm to 10 mm, preferably 20 μm to 5 mm, and more preferably 30 μm to 2 mm. Note that the height (thickness) of the wiring in the substrate having a conductor layer on a surface thereof is usually 3 to 35 μm. Furthermore, from the perspective of improving wiring embedding properties and insulation reliability when formed into a cured resin layer, the difference “thickness of the curable resin composition layer−height (thickness) of the wiring” between the thickness of the curable resin composition layer and the height (thickness) of the wiring in the substrate having a conductor layer on a surface thereof is preferably 35 μm or less, and more preferably 3 to 30 μm.

Furthermore, the substrate having a conductor layer on a surface thereof used in the present invention preferably has pretreatment performed to the conductor layer surface in order to improve adhesion with the curable resin composition layer. A known technique can be used without particular limitation as the method of pretreatment. For example, if the conductor layer is made of copper, examples of the method include oxidation treatment methods wherein a strong alkali oxidizing solution is brought into contact with the conductor layer surface to form a copper oxide layer onto the conductor surface and then roughening is performed, methods of using sodium borohydride, formalin, and the like to perform reduction after oxidizing the conductor layer surface using the previous method, methods of precipitating a plating onto the conductor layer and then roughening, methods of bringing an organic acid into contact with the conductor layer to elute the grain boundary of the copper and then roughening, methods of forming a primer layer onto the conductor layer by a thiol compound, silane compound, or the like. Of these, from the perspective of ease of maintaining the shape of the fine wiring pattern, the method of bringing an organic acid into contact with the conductor layer to elute the grain boundary of the copper and then roughening, and the method of forming a primer layer onto the conductor layer by a thiol compound, silane compound, or the like, are preferable.

In the second step of the manufacturing method of the present invention, examples of the method of laminating the curable resin composition with a supporting body onto the substrate on the curable resin composition layer forming surface side include methods of heat crimping the curable resin composition with a supporting body onto the substrate on the curable resin composition layer forming surface side, or the like.

Examples of the method of heat crimping include methods of overlaying the compact or composite compact with a supporting body so as to be in contact with the aforementioned conductor layer of the substrate, and performing heat crimping (lamination) by a pressurizer such as pressurizing laminators, presses, vacuum laminators, vacuum presses, roll laminator, and the like. By applying heat and pressure, the conductor layer of the substrate surface and the compact or composite compact can be bonded so that a void is substantially not present at the interface thereof. The compact or composite compact is usually laminated onto the conductor layer of the substrate in an uncured or semi-cured state.

The temperature of the heat crimping operation is usually 30 to 250° C. and preferably 70 to 200° C., the pressure to be applied is usually 10 kPa to 20 MPa and preferably 100 kPa to 10 MPa, and the time is usually 30 seconds to 5 hours and preferably 1 minute to 3 hours. Furthermore, heat crimping is preferably performed under reduced pressure in order to improve embedding properties of the wiring pattern and to suppress the generation of bubbles. The pressure of the reduced pressure to perform heat crimping is usually 100 kPa to 1 Pa, and preferably 40 kPa to 10 Pa.

### Third Step

The third step of the manufacturing method of the present invention is a step of performing heating to the pre-cured resin composition layer with a supporting body obtained in the second step, formed from the substrate and the curable resin composition layer with a supporting body, to thermally cure the curable resin composition layer to form a cured resin layer.

The heating temperature of the first heating in the third step may be appropriately set according to the curing temperature of the curable resin composition layer or the type of the supporting body, but is preferably 100 to 250° C., preferably 120 to 220° C., and more preferably 150 to 210° C. Furthermore, the heating time of the first heating in the third step is usually 0.1 to 3 hours and preferably 0.25 to 1.5 hours. The method of heating is not particularly limited, and may be performed by using an electric oven or the like, for example. Furthermore, the thermal curing is preferably performed in an atmosphere from the perspective of productivity.

### Fourth Step

The fourth step of the manufacturing method of the present invention is a step of performing hole punching from the supporting body side of the cured composite with a supporting body obtained in the third step to form a via hole in the cured resin layer.

In the fourth step, the method for forming the via hole is not particularly limited, but the via hole can be formed by performing hole punching by a physical process using drills, lasers, plasma etching, and the like, from the supporting body side. Of these methods, a method using a laser (carbon dioxide gas laser, excimer laser, UV laser, UV-YAG laser, and the like), in other words, a method of irradiating a laser from the supporting body side to form a via hole is preferable because a finer via hole can be formed without impairing the characteristics of the cured resin layer. In the manufacturing method of the present invention, the supporting body is left in an attached condition, and hole punching from the supporting body side is performed to form a via hole in the cured resin layer, and therefore, a via hole with a small diameter (for example, the top diameter is preferably 5 to 100 μm, more preferably 8 to 50 μm, and particularly preferably 10 to 30 μm) can be formed with a high aperture ratio (bottom diameter/top diameter).

### Fifth Step

The fifth step of the manufacturing method of the present invention is a step of removing the resin residue in the via hole of the cured composite after forming the via hole in a condition where the supporting body remains attached.

The method of removing the resin residue in the via hole is not particularly limited, and examples include: a method of bringing the cured composite in contact with a solution (desmear liquid) of an oxidizing compound such as permanganate or the like in a condition where the supporting body remains attached; a method of performing a plasma treatment in the vial hole for the cured composite in a condition where the supporting remains attached; and the like.

With the manufacturing method of the present invention, a process of removing resin residue in the via hole is performed in a condition where the supporting body remains attached, and therefore, a portion other than the via hole, and specifically a cured resin layer surface portion contacting the supporting body is brought into contact with a solution of an oxidizing compound such as permanganate or the like, or exposed to plasma treatment, and thus the resin residue in the via hole can be appropriately removed while effectively preventing problems such as roughening or the like. Furthermore, the cured resin layer after peeling the supporting body can have low surface roughness thereby, and therefore, electrical properties as an electric insulating material can be excellent, and the resin residue in the via hole can be appropriately removed, and therefore, the conductive reliability of the via hole can be enhanced.

In particular, when brought into contacting with a solution of an oxidizing compound such as permanganate or the like, or exposed to plasma treatment, the cured resin layer roughens, and if plasma treatment is used, a resin curable layer surface oxidizes or the resin itself is damaged, and thus a problem occurs where the electrical properties of the cured resin layer is greatly reduced. In contrast, with the manufacturing method of the present invention, a process of removing resin residue in the via hole is performed in a condition where the supporting body remains attached, and therefore, the resin residue in the via hole can be appropriately removed while effectively preventing the problems from occurring.

Examples of the method of removing the resin residue in the via hole include: the aforementioned method of bringing into contact with a solution of an oxidizing compound such as permanganate or the like; the method of performing a plasma treatment; and the like, but from the perspective of being able to minimize surface roughness, or from the perspective of being able to conveniently perform treatment in a condition where the supporting body remains attached, the method of performing a plasma treatment is preferred.

The plasma treatment method can be performed using a vacuum plasma device, ambient plasma device, or the like, for example. Furthermore, a conventionally known plasma can be used as the plasma, such as oxygen plasma or other plasma using a reactive gas, argon plasma, helium plasma or other plasma using an inert gas, or plasma of mixed gases thereof. Of these, oxygen plasma is preferably used. The treatment time when performing the plasma treatment is not particularly limited, but is preferably 1 second to 30 minutes, and more preferably 10 seconds to 10 minutes.

Furthermore, the method of bringing into contact with a solution of an oxidizing compound such as permanganate or the like is not particularly limited, and examples include: a method of oscillating and immersing the cured composite after forming the via hole in a 60 to 80° C. aqueous solution adjusted to a sodium permanganate concentration of 60 g/L and a sodium hydroxide concentration of 28 g/L, in a condition where the supporting body remains attached, for 1 to 50 minutes; a method of filling the aqueous solution in the via hole; and the like.

### Sixth Step

The sixth step of the manufacturing method of the present invention is a step of peeling the supporting body from the cured composite with a supporting body to obtain the cured composite formed from the substrate and the cured resin layer. The method of peeling the supporting body is not particularly limited.

### Seventh Step

The seventh step of the manufacturing method of the present invention is a step of forming a dry plated conductor layer by dry plating an inner wall surface of the via hole and cured resin layer of the cured composite formed from the substrate and cured resin layer, obtained by peeling the supporting body.

With the manufacturing method of the present invention, by forming the conductor layer by dry plating, a fine conductor layer can be formed with high adhesion, even if the surface roughness of the cured resin layer is low.

Note that the dry plating is not particularly limited, and may be a method where water, solvent, or the like essentially do not intervene, and examples include a sputtering method, vacuum deposition method, ion plating method, and the like. Of these, a sputtering method is preferred from the perspective of being above to form a finer conductor layer with higher adhesion.

Examples of a method of forming a dry plated conductor layer using a sputtering method include a method of causing Ar ions to collide with a sputtering target which is a raw material of the dry plated conductor layer, in a vacuum to provide energy to emit atoms configuring the sputtering target so as to adhere to an inner wall surface of the via hole and the cured resin layer, and the like. Furthermore, examples of the sputtering method include a DC magnetron method and RF magnetron method, and either method can be used.

The thickness of the dry plated conductor layer formed on an inner wall surface of the via hole and the cured resin layer is not particularly limited, but is preferably 50 to 500 nm, and more preferably 100 to 300 nm.

Furthermore, after forming the dry plated conductor layer, the cured composite surface can be brought into contact with an antirust agent to perform an antirust treatment. Furthermore, after the dry plated conductor layer is formed, the dry plated conductor layer may be heated to improve adhesion or the like. The heating temperature is usually 50 to 350° C., and preferably 80 to 250° C. Note that the heating can be performed under pressurized conditions. Examples of the pressurizing method include using physical pressurizing means by hot press machines, pressurized heating rolls, and the like. The pressure applied is usually 0.1 to 20 MPa, and preferably 0.5 to 10 MPa. High adhesion between the dry plated conductor layer and the electrical insulating layer can be secured within these ranges.

Furthermore, growing the plating by further performing wet plating on the dry plated conductor layer that was formed by the dry plating method is preferable. The wet plating is not particularly limited, but from the perspective of conveniently and appropriately growing plating, electrolytic plating is preferred. Furthermore, the conductor can be filled into the via hole by the electrolytic plating, and thick plating can be performed on the cured resin layer. When performing thick plating onto the cured resin layer by electrolytic plating, a resist pattern for plating is preferably formed on the dry plated conductor layer formed by the dry plating method and then electrolytic plating is preferably performed to grow the plating, and then the resist is preferably removed and the dry plated conductor layer is preferably etched into a pattern by etching to form a conductor pattern formed from the dry plated conductor layer and wet plated conductor layer. Furthermore, the conductor pattern formed by this method is usually formed from a patterned dry plated conductor layer and the dry plated conductor layer grown on thereon.

The laminate body obtained by the manufacturing method of the present invention is obtained through the aforementioned first step to seventh step, and thus provides a cured resin layer with high adhesion to a conductor layer, low surface roughness, and where a small diameter via hole with excellent conduction reliability and fine wiring can be formed, and therefore suitable use as a multilayer circuit board is possible by taking advantage of the properties thereof. Specifically, the laminate body obtained by the manufacturing method of the present invention has an average surface roughness Ra (in accordance with JIS B0601-2001) of the cured resin layer that is preferably suppressed to 200 nm or less, and more preferably 100 nm or less, and a ten point average surface roughness Rzjis (in accordance with Appendix 1 of JIS B0601-2001) that is preferably suppressed to 2000 nm or less, and more preferably 1000 nm or less. Furthermore, the laminated body obtained by the manufacturing method of the present invention has a peeling strength (in accordance with JIS C6481-1996) between the cured resin layer and conductor layer that is preferably 5 N/cm or greater, and more preferably 6 N/cm or greater, and thereby, provides a cured resin layer with low surface roughness and high adhesion with regard to the conductor layer.

Furthermore, by using the laminated body thus obtained by the manufacturing method of the present invention as a substrate used in the second step of the manufacturing method of the present invention and by repeatedly performing the third step to seventh step, further multilayering can be performed to thereby form a desired multilayer circuit board.

### EXAMPLES

The present invention is described in further detail by the examples and comparative examples below. Note that “parts” and “%” in the examples are on a weight basis unless otherwise specified. Various physical properties were evaluated according to the method below.

### (1) Desmearity

For a cured composite after forming a via hole and performing a desmear treatment (desmear treatment by plasma treating or desmear treatment by an aqueous solution of permanganate), the via hole after desmear treating was observed with an electron microscope (magnification: 1000 times) to observe the resin residue in the via hole, and then evaluation was performed according to the criteria below.

A: No remaining resin at the center of a via bottom or around the via bottom

B: Remaining resin is present at the center of the via bottom, but no remaining resin around the via bottom

C: Remaining resin is present in the entire via bottom

### (2) Fine Wiring Formability

For a cured composite forming a dry plating layer, a wiring pattern was formed by performing etching on the formed dry plating layer using SAC700W3C manufactured by JCU, and then the formed wiring pattern was evaluated according to the criteria below.

A: 2/2 μm line and space (L/S) wiring was formed.

B: 4/4 μm line and space (L/S) wiring was formed.

C: 6/6 μm line and space (L/S) wiring was formed.

### (3) Surface Roughness of Cured Resin Layer

The surface roughness was measured at five points within a measurement range of 91 μm×120 μm of a surface of a portion where a cured resin layer of the obtained multilayer printed wiring plate is exposed, using a surface shape measuring device (WYKO NT1100 manufactured by VICO INSTRUMENTS), and a maximum value of the surface roughness obtained by the measurement results was evaluated according to the following criteria.

A: Ra is less than 100 nm

B: Ra is 100 nm or greater and less than 200 nm

C: Ra is 200 nm or greater

### (4) Adhesion Between the Cured Resin Layer and the Conductor Layer (Peeling Strength)

For the obtained multilayer printed wiring board, the peeling strength between the cured resin layer (electrical insulating layer) and the conductor layer (dry plated layer and electrolytic copper plating film) was measured in accordance with JIS C6481-1996, and then evaluated according to the criteria below.

A: Peeling strength is 5 N/cm or greater

B: Peeling strength is 4 N/cm or greater and less than 5 N/cm

C: Peeling strength is less than 4 N/cm

### Synthesis Example 1

As a first stage of polymerization, 35 molar parts of 5-ethylidene-bicyclo [2.2.1]hepta2-en, 0.9 molar parts of 1-hexene, 340 molar parts of anisole, and 0.005 molar parts of ruthenium 4-acetoxybenzylidene (dichloro) (4,5-dibromo1,3-dimesityl4-imidazolin-2-ylidene) (tricyclohexylphosphine) (C1063, manufactured by Wako Pure Chemical Industries) were incorporated in a nitrogen substituted pressure resistant glass reactor, and polymerization reaction was performed by stirring at 80° C. for 30 minutes to obtain a solution of a norbornene-based ring-opening polymer.

Next, as a second stage of polymerization, 45 molar parts of tetracyclo [6.5.0.12,5.08,13]trideca3,8,10,12-tetraene, 20 molar parts of bicyclo [2.2.1]hept-2-ene-5,6-dicarboxylic anhydride, 250 molar parts of anisole, and 0.01 molar parts of C1063 were added to the solution obtained in the first stage of polymerization, and polymerization reaction was performed by stirring at 80° C. for 5 hours to obtain a solution of a norbornene-based ring-opening polymer. For the solution, gas chromatography was measured, and it was confirmed that no monomers were substantially remaining, and the polymerization conversion rate was 99% or higher.

Next, the solution of the obtained ring-opening polymer was added to a nitrogen substituted autoclave with mixer, 0.03 molar parts of C1063 were added, and a hydrogenation reaction was performed by stirring at 150° C. at a hydrogen pressure of 7 MPa for 5 hours to obtain a solution of an alicyclic olefin polymer (1) which is a hydrogation adduct of the norbornene-based ring-opening polymer. The weight average molecular weight of the alicyclic olefin polymer (1) was 60000, the number average molecular weight was 30000 and the molecular weight distribution was 2. Furthermore, the hydrogenation ratio was 95%, and the content rate of the repeating unit having a carboxylic anhydride group was 20 mol %. The solid content concentration of the solution of the alicyclic olefin polymer (1) was 22%.

### Example 1

### Preparation of the First Thermosetting Resin Composition

50 parts of a biphenyldimethylene skeleton novolak epoxy resin as the polyvalent epoxy compound (A) having a biphenyl structure (trade name “NC-3000L”, manufactured by Nippon Kayaku Co., Ltd., epoxy equivalent of 269), 50 parts of tetrakis hydroxyphenylethane type epoxy compound as the epoxy group (B) containing a trivalent or higher polyvalent glycidyl group (trade name “1031S”, manufactured by Mitsubishi Chemical Corporation, epoxy equivalent of 200, softening point of 90° C.), 30 parts (15 parts in terms of cresol novolac resin containing a triazine structure) of cresol novolak resin containing a triazine structure as the phenol resin (C) containing a triazine structure (trade name “phenolite LA-3018-50P”, propylene glycol monomethyl ether solution with a nonvolatile content of 50%, manufactured by DIC Corporation, active hydroxyl group equivalent of 154), 115.3 parts (75 parts in terms of active ester compounds) of active ester compound as the active ester compound (D) (trade name “Epiclon HPC-8000-65T”, toluene solution having a nonvolatile content of 65%, manufactured by DIC Corporation, active ester group equivalent of 223), 350 parts of silica as a filler (trade name “SC2500-SXJ”, manufactured by Admatechs), 1 part of hindered phenol antioxidant as an anti-aging agent (trade name “Irganox (registered trademark) 3114”, manufactured by BASF), and 110 parts of anisole were mixed and stirred with a planetary stirrer for 3 minutes. In addition, 8.3 parts of a solution in which 30% 1-benzyl-2-phenylimidazole was dissolved in anisole (2.5 parts in terms of 1-benzyl-2-phenylimidazole) was mixed therein as the cure promoting agent, and stirred with a planetary stirrer for 5 minutes to obtain a varnish of the first thermosetting resin composition. Note that the amount of filler in the varnish was 64% in terms of solid content.

### The Second Thermosetting Resin Composition

454 parts of the solution of the alicyclic olefin polymer (1) obtained in Synthesis Example (100 parts in terms of alicyclic olefin polymer (1)), 36 parts of the polyvalent epoxy compound having a dicyclopentadiene skeleton as a curing agent (trade name “Epiclon HP7200L”, manufactured by DIC Corporation, “Epiclon” is a registered trademark), 24.5 parts of silica as an inorganic filler (trade name “Admafine SO-C1”, manufactured by Admatechs, average particle size of 0.25 μm, “Admafine” is a registered trademark), 1 part of tris (3,5-di-t-butyl-4-hydroxybenzyl)-isocyanurate as an anti-aging agent (trade name “Irganox (registered trademark) 3114”, manufactured by BASF), 0.5 parts of 2-[2-hydroxy-3,5-bis (α, α-dimethylbenzyl) phenyl]-2H1-benzotriazole as an ultraviolet absorber, and 0.5 parts of 1-benzyl-2-phenylimidazole as a curing promoting agent were mixed with anisole, and by mixing so that the compounding agent concentration was 16%, a varnish of the second thermosetting resin composition was obtained.

### Preparation of the Cured Composite

The varnish of the second thermosetting resin composition that was obtained was applied onto a polyethylene terephthalate film (supporting body, thickness of 50 μm) having a release layer on a surface thereof using a wire bar, and then in a nitrogen atmosphere, dried at 80° C. for 5 minutes to obtain a film with a supporting body formed from an uncured second thermosetting resin composition, on which a second resin layer (plated layer) with a thickness of 3 μm was formed.

Next, the varnish of the first thermosetting resin composition that was obtained was applied onto the formed surface of the second resin layer formed from the second thermosetting resin composition of the film with a supporting body, using a doctor blade (manufactured by Tester Sangyo Co., Ltd.) and an autofilm applicator (manufactured by Tester Sangyo Co., Ltd.), and then drying was performed in a nitrogen atmosphere at 80° C. for 5 minutes to obtain a curable resin composition layer with a supporting body, which the second resin layer and the first resin layer (adhesive layer) with a total thickness of 20 μm was formed thereon. The curable resin composition layer with a supporting body was formed in the order of the supporting body, the second resin layer formed from the second thermosetting resin composition, and then the first resin layer formed from the first thermosetting resin composition.

Next, separately from the above, on a surface of a core material obtained by impregnating a varnish containing a glass filler and an epoxy compound not containing a halogen into a glass fiber, a conductor layer with a wiring width and distance between the wires of 50 μm, with a thickness of 18 μm, and that was treated with microetching by bringing a surface thereof into contact with an organic acid, was formed onto a double-sided copper clad substrate surface with a thickness of 0.8 mm, 160 mm square (length of 160 mm, width of 160 mm) attached with copper with a thickness of 18 μm, to obtain an inner layer substrate.

On both surfaces of the inner layer substrate, the obtained curable resin composition layer with a supporting body cut into 150 mm squares with the supporting body attached, were attached together so that the surface of the curable resin composition layer was on the inside, and then a vacuum laminator with a heat resistant rubber press plate on the top and bottom thereof was used to reduce the pressure to 200 Pa and perform heat crimping lamination at a temperature of 110° C. and a pressure of 0.1 MPa for 60 seconds. Next, after left to stand at room temperature for 30 minutes, by heating (the first heating) at 180° C. for 30 minutes and curing the curable resin composition layer, a cured resin layer (electrical insulating layer) was formed.

Next, for the cured resin layer formed on both surfaces of the inner substrate, a UV laser processor (product name “LUC-2K21”, manufactured by Hitachi Via Mechanics, Ltd.) was used in a condition where the supporting body remained attached, and by irradiating the UV laser from the supporting body side with a mask diameter of 0.8 mm and an output of 0.4 W in 100 shot bursts, a via hole with an opening size of 25 μm was formed in the cured resin layer.

### Desmear Treatment Step by Plasma Treatment

Next, for the obtained cured composite in a condition where the supporting body remains attached, a plasma treatment was performed from the supporting body side using a plasma generating device (product “NM-FP1A” manufactured by Panasonic Factory Solutions) in order to remove resin residue in the via hole formed as described above. Note that the conditions at this time were set to a treatment time of 10 minutes, output of 500 W, and gas pressure of 20 pA at room temperature under an O₂ gas atmosphere. Next, the supporting body was peeled from the cured composite after plasma treating. Furthermore, a desmearity evaluation was performed based on the aforementioned method for the cured composite after plasma treating, with the supporting body peeled off.

### Forming Dry Plating Layer by Sputtering

A 250-nm thick dry plating layer was formed by a sputtering device (product name “CFS-4ES/i-Miller” manufactured by Shibaura Eletech Corporation) using a copper target as the sputtering target, on a cured resin layer surface (second resin layer surface after curing, formed from the second thermosetting resin composition) and via hole inner wall surface of the cured composite with the supporting body peeled off. Furthermore, for the cured composite forming the dry plating layer thereby, an annealing treatment was performed for 30 minutes at 150° C., and then a fine wiring formability evaluation was performed based on the aforementioned method, using the annealed cured composite.

### Forming Wet Plating Layer

Next, in a condition the annealed cured composite was masked in a predetermined pattern, electrolytic copper plating was performed to fill an electrolytic copper plating (conductor formed by wet plating) in the via hole of the cured composite, and to form a 30-μm thick electrolytic copper plating film (wet plating layer) into a predetermined pattern. Next, after heat treating the cured composite for 60 minutes at 180° C., a portion of the dry plated layers where an electrolytic copper plating film was not formed thereon was removed by etching using SAC700W3C manufactured by JCU to obtain a multilayer printed wiring plate with 2 layers, one on each surface, where a conductor formed from a dry plating layer and electrolytic copper plating (wet plating) was filled in the via hole of the cured composite, and a conductor layer formed from the dry plating layer and electrolytic copper plating film (wet plating layer) was formed on the cured resin layer (electrical insulating layer) of the cured composite. Furthermore, the obtained multilayer printed wiring board was used to measure the surface roughness of the cured resin layer and evaluate adhesion (peeling strength) between the cured resin layer and the conductor layer. The results are shown in Table 1.

### Comparative Example 1

Other than peeling off the supporting body after adhering the curable resin composition layer with a supporting body to both surfaces of an inner layer substrate, and then in a condition with the supporting body peeled off curing the curable resin composition layer, forming the via hole, and performing a desmear treatment by a plasma treatment, a cured composite and multilayer printed wiring plate were obtained similarly to Example, and evaluations were similarly performed. The results are shown in Table 1.

### Comparative Example 2

Other than an electroless plating layer by electroless plating was formed in place of forming the dry plating layer by sputtering, and then forming an electrolytic copper plating film on the electroless plating layer, a cured composite and multilayer printed wiring plate were obtained similarly to Example 1, and evaluations were similarly performed. The results are shown in Table 1. Note that forming the electroless plating layer was performed by the same method as Example 2 in WO 2012/090980.

### Comparative Example 3

Other than peeling off the supporting body after adhering the curable resin composition layer with a supporting body to both surfaces of an inner layer substrate, and then in a condition with the supporting body peeled off, curing the curable resin composition layer, forming a via hole, and performing a desmear treatment by a method using an aqueous solution of permanganate in place of the method by a plasma treatment, a cured composite and multilayer printed wiring plate were obtained similarly to Comparative Example 2, and evaluations were similarly performed. The results are shown in Table 1. Note that the desmear treatment using an aqueous solution of permanganate was performed similarly to Example 2 in WO 2012/090980.

TABLE 1

| | | | |
|---|---|---|---|
| | Comparative | Comparative | Comparative |
| Example 1 | Example 1 | Example 2 | Example 3 |

Manufacturing condition

| | | | | |
|---|---|---|---|---|
| Peeling | After curing | Before curing | After curing | Before curing |
| timing of | resin layer, | resin layer | resin layer, | resin layer |
| supporting | forming via | | forming via | |
| body | hole, and | | hole, and | |
| | desmear | | desmear | |
| | treatment | | treatment | |
| Desmear | Plasma | Plasma | Plasma | Method using |
| treatment | treatment | treatment | treatment | permanganate |
| method | | | | aqueous |
| | | | | solution |
| Method | Sputtering | Sputtering | Electroless | Electoless |
| of forming | method | method | plating | plating |
| conductor | | | method | method |
| layer | | | | |
| directly | | | | |
| formed on | | | | |
| cured resin | | | | |
| layer | | | | |

Evaluation

| | | | | |
|---|---|---|---|---|
| Desmearity | A | A | A | A |
| Fine wiring | A | B | A | C |
| formability | | | | |
| Surface | A | B | A | C |
| roughness | | | | |
| of cured | | | | |
| resin layer | | | | |
| Peeling | A | A | C | A |
| Strength | | | | |

As shown in Table 1, with the manufacturing method of the present invention, the resin residue in the via hole was appropriately removed (excellent desmearity), and thereby, results were achieved where a laminate body provided with a cured resin layer (electrical insulating layer) with excellent conduction reliability, that can form fine wiring, that has low surface roughness, and excellent adhesion with regard to a conductor layer (Example 1).

On the other hand, if the curable resin composition layer was cured, the via hole was formed, and desmear treatment (either method by a plasma treatment or method by an aqueous solution of permanganate) was performed in a condition with the supporting body peeled off, results were achieved where fine wiring could not be formed, and the surface roughness of the cured resin layer was high (Comparative Examples 1, 3).

Furthermore, if a conductor layer directly formed on the cured resin layer is formed by electroless plating in place of forming by dry plating, results were achieved where adhesion between the cured resin layer and conductor layer was inferior (Comparative Example 2).

1. A manufacturing method of a laminate body, comprising:
a first operation of forming onto a supporting body a curable resin composition layer formed from a thermosetting resin composition to obtain a curable resin composition layer with a supporting body;
a second operation of laminating the aforementioned curable resin composition layer with a supporting body onto a substrate on a curable resin composition layer forming surface side to obtain a pre-cured composite with a supporting body formed from a substrate and a curable resin composition layer with a supporting body;
a third operation of performing heating of the aforementioned composite and thermally curing the aforementioned curable resin composition layer to form a cured resin layer to obtain a cured composite with a supporting body formed from a substrate and a cured resin layer with a supporting body;
a fourth operation of performing hole punching from the aforementioned supporting body side of the aforementioned cured composite with a supporting body to form a via hole in the aforementioned cured resin layer;
a fifth operation of removing resin residue in the via hole of the aforementioned cured composite;
a sixth operation of peeling the aforementioned supporting body from the aforementioned cured composite with a supporting body to obtain a cured composite formed from a substrate and a cured resin layer; and
a seventh operation of forming a dry plated conductor layer by dry plating on an inner wall surface of the via hole of the aforementioned cured composite and on the aforementioned cured resin layer.

2. The manufacturing method of a laminate body according to claim 1, wherein the removal of resin residue in a via hole in the fifth operation is performed by plasma treatment.

3. The manufacturing method of a laminate body according to claim 1, wherein the dry plating in the seventh operation is performed by a sputtering method.

4. The manufacturing method of a laminate body according to claim 1, further comprising an eighth operation of further performing wet plating on the drying plated conductor layer to form a wet plated conductor layer on the dry plated conductor layer.

5. The manufacturing method of a laminate body according to claim 4, wherein the via hole is filled with the wet plate conductor layer formed on the dry plated conductor layer in the eighth operation.

6. A laminate body obtained by a manufacturing method of the laminate body, comprising:
a first operation of forming onto a supporting body a curable resin composition layer formed from a thermosetting resin composition to obtain a curable resin composition layer with a supporting body;
a second operation of laminating the aforementioned curable resin composition layer with a supporting body onto a substrate on a curable resin composition layer forming surface side to obtain a pre-cured composite with a supporting body formed from a substrate and a curable resin composition layer with a supporting body;
a third operation of performing heating of the aforementioned composite and thermally curing the aforementioned curable resin composition layer to form a cured resin layer to obtain a cured composite with a supporting body formed from a substrate and a cured resin layer with a supporting body;
a fourth operation of performing hole punching from the aforementioned supporting body side of the aforementioned cured composite with a supporting body to form a via hole in the aforementioned cured resin layer;
a fifth operation of removing resin residue in the via hole of the aforementioned cured composite;
a sixth operation of peeling the aforementioned supporting body from the aforementioned cured composite with a supporting body to obtain a cured composite formed from a substrate and a cured resin layer; and
a seventh operation of forming a dry plated conductor layer by dry plating on an inner wall surface of the via hole of the aforementioned cured composite and on the aforementioned cured resin layer.

7. A multilayer circuit board comprising a laminate body obtained by a manufacturing method of the laminate body, comprising:
a first operation of forming onto a supporting body a curable resin composition layer formed from a thermosetting resin composition to obtain a curable resin composition layer with a supporting body;
a second operation of laminating the aforementioned curable resin composition layer with a supporting body onto a substrate on a curable resin composition layer forming surface side to obtain a pre-cured composite with a supporting body formed from a substrate and a curable resin composition layer with a supporting body;
a third operation of performing heating of the aforementioned composite and thermally curing the aforementioned curable resin composition layer to form a cured resin layer to obtain a cured composite with a supporting body formed from a substrate and a cured resin layer with a supporting body;
a fourth operation of performing hole punching from the aforementioned supporting body side of the aforementioned cured composite with a supporting body to form a via hole in the aforementioned cured resin layer;
a fifth operation of removing resin residue in the via hole of the aforementioned cured composite;
a sixth operation of peeling the aforementioned supporting body from the aforementioned cured composite with a supporting body to obtain a cured composite formed from a substrate and a cured resin layer; and
a seventh operation of forming a dry plated conductor layer by dry plating on an inner wall surface of the via hole of the aforementioned cured composite and on the aforementioned cured resin layer.
